(19) United States
(12) Patent Application Publication
(10) Pub. No.: US 2024/0421048 A1
(43) Pub. Date: Dec. 19, 2024

(54) SEMICONDUCTOR DEVICE

(71) Applicant: Rohm Co., Ltd., Kyoto-shi (JP)

(72) Inventors: Koki TANIZAWA, Kyoto-shi (JP); Shinichi HIRATA, Kyoto-shi (JP)

(21) Appl. No.: 18/816,403

(22) Filed: Aug. 27, 2024

Related U.S. Application Data
(63) Continuation of application No. PCT/JP2023/006010, filed on Feb. 20, 2023.

(30) Foreign Application Priority Data
Mar. 7, 2002 (JP) 2022-034615

(51) Int. Cl. H01L 23/495; H01L 23/00; H01L 23/31

(52) U.S. Cl. CPC H01L 23/49562; H01L 23/3107; H01L 23/49513; H01L 24/48; H01L 24/45; H01L 2224/45124; H01L 2224/45144; H01L 2224/45147; H01L 2224/48248; H01L 2924/13091

(57) ABSTRACT

A semiconductor device includes first and second leads, a semiconductor element, and conductive members. The first lead includes a base including a first surface on which the semiconductor element is mounted. Each conductive member includes first and second end portions. The semiconductor element includes first and second obverse-surface electrodes formed on an element obverse surface. A first end portion of each conductive member is bonded to the first or the second obverse-surface electrode. The second lead includes first and second portions of an elongated shape. In plan view, the first portion is located on a first side in a first direction with respect to the base. The second portion is located on a first side in a second direction with respect to the base, extending in the first direction. The conductive members include a first conductive member whose second end portion is bonded to the second portion.

### TECHNICAL FIELD

The present disclosure relates to a semiconductor device.

### BACKGROUND ART

Various configurations have been proposed fora semiconductor device including a semiconductor element. JP-discloses an example of a conventional A-2017-135241 semiconductor device. The semiconductor device disclosed in JP-A-2017-135241 includes a semiconductor element, a plurality of leads, a plurality of wires, and a sealing resin. The semiconductor element is mounted on one of the leads. Each of the wires is bonded to the semiconductor element and a lead other than the lead on which the semiconductor element is mounted. The other lead has a plurality of terminals. In plan view, the other lead is adjacent to the lead on which the semiconductor element is mounted, in a certain direction on a side where the terminals are arranged (downward in FIG. 3 of JP-A-2017-135241). The sealing resin covers a portion of each lead, the wires, and the semiconductor element.

When the number of wires bonded to the semiconductor element increases in the conventional semiconductor device described above, the bonding positions of the wires to the semiconductor element are arranged in multiple rows (see FIG. 3 in JP-A-2017-135241) in order to avoid interference of the wires at their bonding positions to the semiconductor element. Some of the wires arranged in this manner are relatively long. This may cause a problem such as a wire sweep when a sealing resin is formed.

### BRIEF DESCRIPTION OF THE DRAWINGS

FIG. 1 is a plan view showing a semiconductor device according to a first embodiment of the present disclosure.

FIG. 2 is a bottom view showing the semiconductor device in FIG. 1.

FIG. 3 is a plan view showing the semiconductor device in FIG. 1 (as seen through a sealing resin).

FIG. 4 is a cross-sectional view along line IV-IV in FIG. 3.

FIG. 5 is a cross-sectional view along line V-V in FIG. 3.

FIG. 6 is a cross-sectional view along line VI-VI in FIG. 3.

FIG. 7 is a plan view showing a semiconductor device (as seen through a sealing resin) according to a first variation of the first embodiment.

FIG. 8 is a plan view showing a semiconductor device (as seen through a sealing resin) according to a second variation of the first embodiment.

FIG. 9 is a plan view showing a semiconductor device (as seen through a sealing resin) according to a third variation of the first embodiment.

FIG. 10 is a plan view showing a semiconductor device (as seen through a sealing resin) according to a fourth variation of the first embodiment.

FIG. 11 is a plan view showing a semiconductor device (as seen through a sealing resin) according to a fifth variation of the first embodiment.

FIG. 12 is a plan view showing a semiconductor device (as seen through a sealing resin) according to a sixth variation of the first embodiment.

FIG. 13 is a plan view showing a semiconductor device according to a second embodiment of the present disclosure.

FIG. 14 is a bottom view showing the semiconductor device in FIG. 13.

FIG. 15 is a plan view of the semiconductor device in FIG. 13 (as seen through a sealing resin).

FIG. 16 is a cross-sectional view along line XVI-XVI in FIG. 15.

### DETAILED DESCRIPTION OF EMBODIMENTS

The following describes preferred embodiments of the present disclosure in detail with reference to the drawings.

The terms such as “first”, “second” and “third” in the present disclosure are used merely as labels, and are not intended to impose orders on the elements accompanied with these terms.

In the present disclosure, the phrases “an object A is formed in an object B” and “an object A is formed on an object B” include, unless otherwise specified, “an object A is formed directly in/on an object B” and “an object A is formed in/on an object B with another object interposed between the object A and the object B”. Similarly, the phrases “an object A is disposed in an object B” and “an object A is disposed on an object B” include, unless otherwise specified, “an object A is disposed directly in/on an object B” and “an object A is disposed in/on an object B with another object interposed between the object A and the object B”. Similarly, the phrase “an object A is located on an object B” includes, unless otherwise specified, “an object A is located on an object B in contact with the object B” and “an object A is located on an object B with another object interposed between the object A and the object B”. Further, the phrase “an object A overlaps with an object B as viewed in a certain direction” includes, unless otherwise specified, “an object A overlaps with the entirety of an object B” and “an object A overlaps with a portion of an object B”.

### First Embodiment

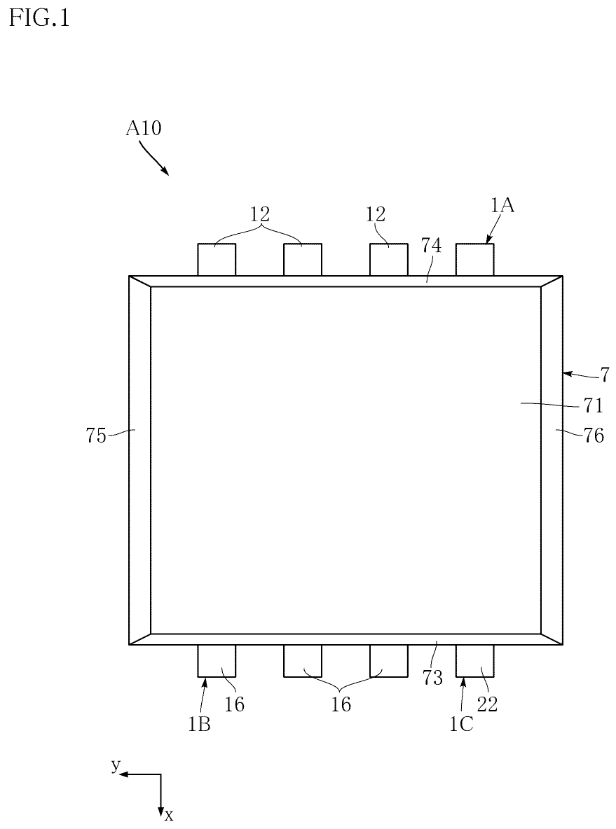

The following describes a semiconductor device A10 according to a first embodiment of the present disclosure, with reference to FIGS. 1 to 6. The semiconductor device A10 has a first lead 1A, a second lead 1B, a third lead 1C, a semiconductor element 3, a plurality of bonding wires 4, and a sealing resin 7.

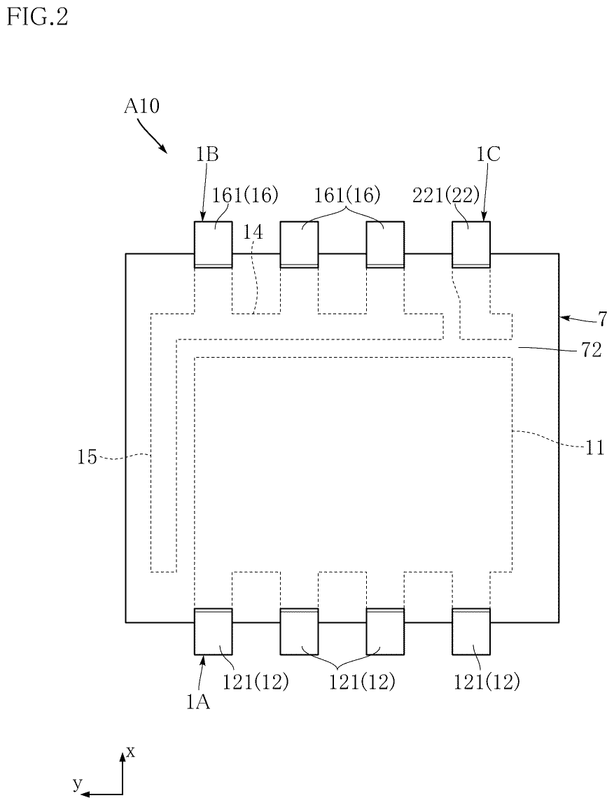

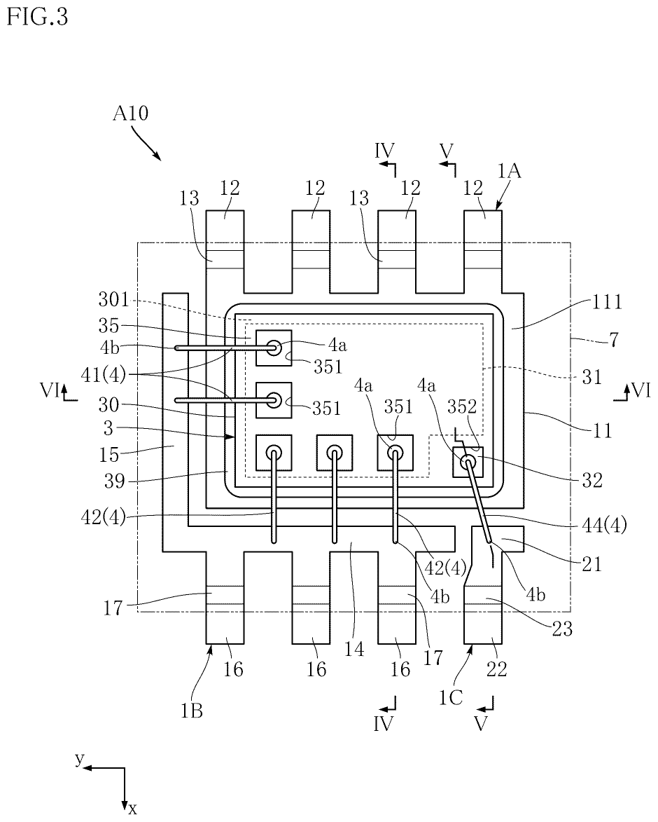

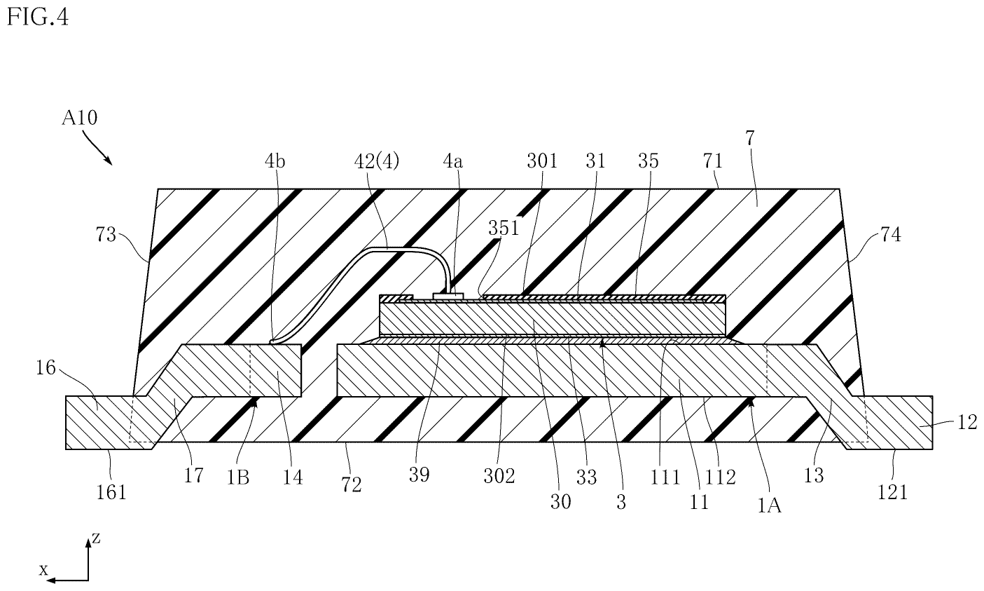

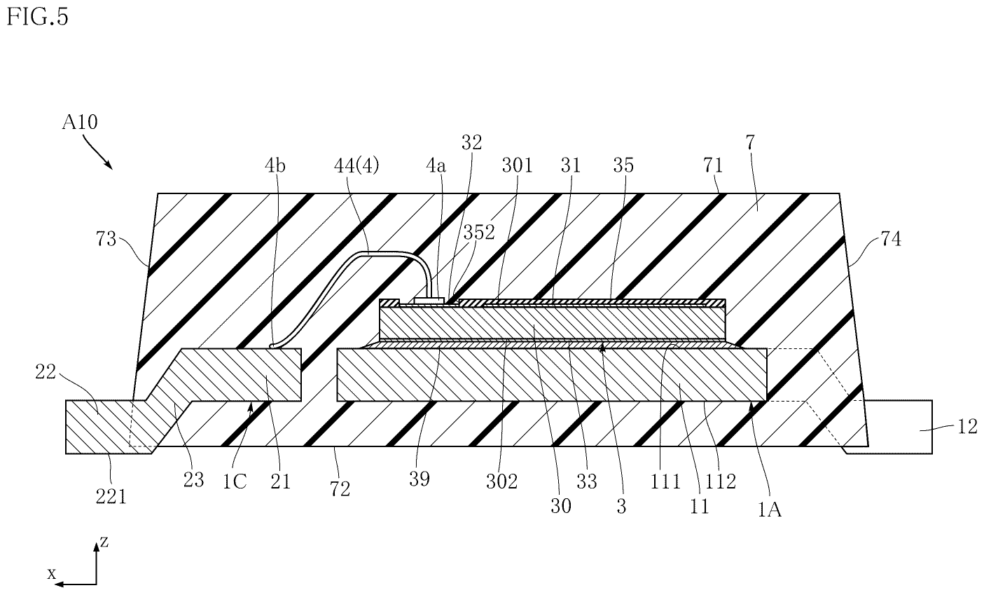

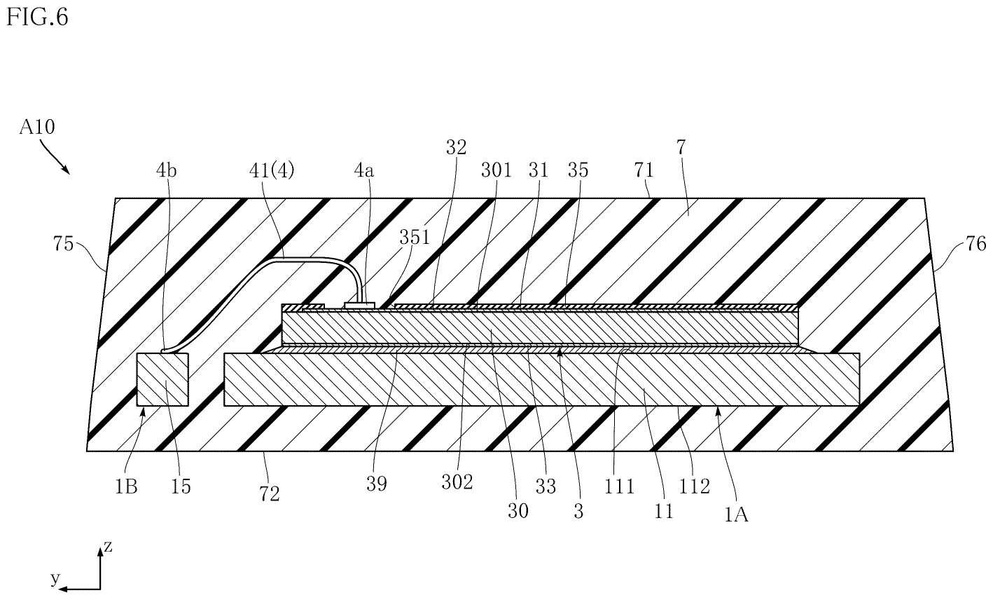

FIG. 1 is a plan view showing the semiconductor device A10. FIG. 2 is a bottom view showing the semiconductor device A10. FIG. 3 is a plan view showing the semiconductor device A10. FIG. 4 is a cross-sectional view along line IV-IV in FIG. 3. FIG. 5 is a cross-sectional view along line V-V in FIG. 3. FIG. 6 is a cross-sectional view along line VI-VI in FIG. 3. Note that FIG. 3 shows the sealing resin 7 as transparent for convenience of understanding.

In the description of the semiconductor device A10, the thickness direction of the semiconductor element 3 is referred to as a “thickness direction z”. A direction perpendicular to the thickness direction z is referred to as a “first direction x”. The direction perpendicular to the thickness direction z and the first direction x is referred to as a “second direction y”. As shown in FIGS. 1 and 2, the semiconductor device A10 has a rectangular shape (or substantially a rectangular shape) as viewed in the thickness direction z. The semiconductor device A10 is not limited to a particular size.

The first lead 1A, the second lead 1B, and the third lead 1C are formed by punching or bending a metal plate (lead frame), for example. The constituent material of the first lead 1A, the second lead 1B, and the third lead 1C is not particularly limited, and may be either one of copper (Cu) and nickel (Ni), or an alloy of Cu or Ni. Each of the first lead 1A, the second lead 1B, and the third lead 1C has a thickness of 0.1 mm to 0.3 mm, for example. Although not illustrated or described in detail, each of the first lead 1A, the second lead 1B, and the third lead 1C is mostly covered with a plating layer, for example. The constituent material of the plating layer is not particularly limited, and may be an alloy containing Sn as a primary component.

As shown in FIG. 3, the first lead 1A, the second lead 1B, and the third lead 1C are spaced apart from each other as viewed in the thickness direction z. As viewed in the thickness direction z, the first lead 1A is the largest and the third lead 1C is the smallest in size.

As shown in FIGS. 3 to 6, the first lead 1A has a die pad 11, a plurality of (four in the present embodiment) first terminal portions 12 and a plurality of (four in the present embodiment) bent portions 13. The die pad 11 has a rectangular shape as viewed in the thickness direction z, for example. The die pad 11 has a first surface 111 and a second surface 112. The first surface 111 faces a first side in the thickness direction z, and the second surface 112 faces the side opposite from the first surface 111 (a second side in the thickness direction z). The semiconductor element 3 is mounted on the first surface 111. In the present embodiment, the entirety of the die pad 11 is covered with the sealing resin 7. The die pad 11 is an example of the “base”.

The first terminal portions 12 are located on a second side (upper side in FIG. 3) in the first direction x with respect to the die pad 11. The first terminal portions 12 extend to the second side in the first direction x. The first terminal portions 12 are spaced apart from each other in the second direction y. Each of the first terminal portions 12 has a reverse-surface mounting portion 121. The reverse-surface mounting portion 121 faces the second side (lower side in FIG. 4) in the thickness direction z. The reverse-surface mounting portion 121 is exposed from the sealing resin 7. The reverse-surface mounting portion 121 is bonded with a bonding material such as solder when the semiconductor device A10 is mounted onto a circuit board (not illustrated). Each of the bent portions 13 connects the die pad 11 and a first terminal portion 12, and is bent as viewed in the second direction y.

As shown in FIGS. 3, 4, and 6, the second lead 1B has a first portion 14, a second portion 15, a plurality of (three in the present embodiment) second terminal portions 16, and a plurality of (three in the present embodiment) bent portions 17. As viewed in the thickness direction z, the first portion 14 is located on a first side (lower side in FIG. 3) in the first direction x with respect to the die pad 11. The first portion 14 extends in the second direction y. As viewed in the thickness direction z, the second portion 15 is located on a first side (left side in FIG. 3) in the second direction y with respect to the die pad 11. The second portion 15 is connected to the first portion 14, and extends in the first direction x. More specifically, the end of the second portion 15 on the first side (lower side in FIG. 3) in the first direction x is connected to the end of the first portion 14 on the first side (left side in FIG. 3) in the second direction y.

The second terminal portions 16 are located on the first side (lower side in FIG. 3) in the first direction x with respect to the first portion 14. The second terminal portions 16 extend to the first side in the first direction x. The second terminal portions 16 are spaced apart from each other in the second direction y. Each of the second terminal portions 16 has a reverse-surface mounting portion 161. The reverse-surface mounting portion 161 faces the second side (lower side in FIG. 4) in the thickness direction z. The reverse-surface mounting portion 161 is exposed from the sealing resin 7. The reverse-surface mounting portion 161 is bonded with a bonding material such as solder when the semiconductor device A10 is mounted onto a circuit board (not illustrated). Each of the bent portions 17 connects the first portion 14 and a second terminal portion 16, and is bent as viewed in the second direction y.

As shown in FIGS. 3 and 5, the third lead 1C has a base end portion 21, a third terminal portion 22, and a bent portion 23. As viewed in the thickness direction z, the base end portion 21 is located on the first side (lower side in FIG. 3) in the first direction x with respect to the die pad 11. The base end portion 21 is also located on a second side (right side in FIG. 3) in the second direction y with respect to the first portion 14 of the second lead 1B. The third terminal portion 22 is located on the first side (lower side in FIG. 3) in the first direction x with respect to the base end portion 21. The third terminal portion 22 extends to the first side in the first direction x. The third terminal portion 22 has a reverse-surface mounting portion 221. The reverse-surface mounting portion 221 faces the second side (lower side in FIG. 5) in the thickness direction z. The reverse-surface mounting portion 221 is exposed from the sealing resin 7. The reverse-surface mounting portion 221 is bonded with a bonding material such as solder when the semiconductor device A10 is mounted onto a circuit board (not illustrated). The bent portion 23 connects the base end portion 21 and the third terminal portion 22, and is bent as viewed in the second direction y.

The semiconductor element 3 is an element that exerts an electrical function of the semiconductor device A10. The type of the semiconductor element 3 is not particularly limited. In the present embodiment, the semiconductor element 3 is configured as a transistor. In the description of the semiconductor device A10, the semiconductor element 3 is a switching element such as an n-channel MOSFET, but may be a p-channel MOSFET instead. As shown in FIGS. 3 to 5, the semiconductor element 3 has an element body 30, a first obverse-surface electrode 31, a second obverse-surface electrode 32, and a reverse-surface electrode 33.

The element body 30 has a rectangular shape as viewed in the thickness direction z. More specifically, the element body 30 (the semiconductor element 3) has an elongated rectangular shape with a length in the second direction y and a width in the first direction x. The element body 30 has an element obverse surface 301 and an element reverse surface 302. The element obverse surface 301 and the element reverse surface 302 face away from each other in the thickness direction z. The element obverse surface 301 faces the same side as the first surface 111 of the die pad 11 in the thickness direction z. Thus, the element reverse surface 302 faces the first surface 111.

The first obverse-surface electrode 31 and the second obverse-surface electrode 32 are arranged on the element obverse surface 301. The reverse-surface electrode 33 is arranged on the element reverse surface 302. The constituent material of the first obverse-surface electrode 31, the second obverse-surface electrode 32, and the reverse-surface electrode 33 may be copper (Cu), aluminum (Al), or an alloy of Cu or Al. In the present embodiment, the first obverse-surface electrode 31 is a source electrode, the second obverse-surface electrode 32 is a gate electrode, and the reverse-surface electrode 33 is a drain electrode.

In the present embodiment, the first obverse-surface electrode 31 covers most of the element obverse surface 301. Specifically, the first obverse-surface electrode 31 is arranged over the area of the rectangular element obverse surface 301, excluding the periphery and a corner (lower right corner in FIG. 3) of the element obverse surface 301. The second obverse-surface electrode 32 is arranged at a corner (lower right corner in FIG. 3) of the element obverse surface 301. The first obverse-surface electrode 31 and the second obverse-surface electrode 32 are examples of the “obverse surface electrode”.

The reverse-surface electrode 33 covers the entirety (or substantially the entirety) of the element reverse surface 302. The reverse-surface electrode 33 is electrically bonded to the first surface 111 (the die pad 11) via a conductive bonding member 39. The conductive bonding member 39 electrically bonds the die pad 11 and the reverse-surface electrode 33. The conductive bonding member 39 is solder, for example.

In the present embodiment, the element obverse surface 301, and the first obverse-surface electrode 31 and the second obverse-surface electrode 32 arranged on the element obverse surface 301 are covered with an insulating film 35. The insulating film 35 has a plurality of openings 351 and an opening 352. The openings 351 overlap with the first obverse-surface electrode 31 as viewed in the thickness direction z. The opening 352 overlaps with the second obverse-surface electrode 32 as viewed in the thickness direction z. The openings 351 and the opening 352 pass through the insulating film 35 in the thickness direction z. As a result, the first obverse-surface electrode 31 is exposed from the openings 351, and the second obverse-surface electrode 32 is exposed from the opening 352. Portions of the first obverse-surface electrode 31 exposed from the openings 351 and a portion of the second obverse-surface electrode 32 exposed from the opening 352 are used to bond the bonding wires 4. The openings 351 include those arranged along the edge of the first obverse-surface electrode 31 located on the first side in the first direction x, and those arranged along the edge of the first obverse-surface electrode 31 located on the first side in the second direction y.

The constituent material of the insulating film 35 is not particularly limited. In the present embodiment, the insulating film 35 may be made of a resin material, such as polyimide resin. Note that the insulating film 35 does not necessarily have to be provided.

As shown in FIG. 3, each of the bonding wires 4 is bonded to the first obverse-surface electrode 31 or the second obverse-surface electrode 32 of the semiconductor element 3 and to the second lead 1B or the third lead 1C. Each bonding wire 4 has a first end portion 4a and a second end portion 4b. The first end portion 4a is bonded to the first obverse-surface electrode 31 or the second obverse-surface electrode 32, and comprises a first bonding portion. The second end portion 4b is bonded to the second lead 1B or the third lead 1C, and comprises a second bonding portion. The constituent material of the bonding wires 4 is not particularly limited, and may include one of gold (Au), aluminum, or copper.

In the present embodiment, the bonding wires 4 include a plurality of first wires 41, a plurality of second wires 42, and a fourth wire 44.

Each of the plurality of (two in the present embodiment) first wires 41 extends in the second direction y as viewed in the thickness direction z. The first end portion 4a of each first wire 41 is bonded to the first obverse-surface electrode 31 exposed from the openings 351. Specifically, the first end portion 4a of each first wire 41 is bonded to a portion of the first obverse-surface electrode 31 exposed from one of the openings 351 arranged on the first side in the second direction y. The second end portion 4b of each first wire 41 is bonded to the second portion 15 of the second lead 1B. The first wires 41 are spaced apart from each other in the first direction x.

Each of the plurality of (three: the present embodiment) second wires 42 extends in the first direction x as viewed in the thickness direction z. The first end portion 4a of each second wire 42 is bonded to the first obverse-surface electrode 31 exposed from the openings 351. Specifically, the first end portion 4a of each second wire 42 is bonded to a portion of the first obverse-surface electrode 31 exposed from one of the openings 351 arranged on the first side in the first direction x. The second end portion 4b of each second wire 42 is bonded to the first portion 14 of the second lead 1B. The second wires 42 are spaced apart from each other in the second direction y.

The fourth wire 44 extends generally in the first direction x as viewed in the thickness direction z. The first end portion 4a of the fourth wire 44 is bonded to the second obverse-surface electrode 32 exposed from the opening 352. The second end portion 4b of the fourth wire 44 is bonded to the base end portion 21 of the third lead 1C.

The bonding wires 4 having the configuration as described above are examples of the “conductive members”. Each of the first wires 41 is an example of the “first conductive member”, each of the second wires 42 is an example of the “second conductive member”, and the fourth wire 44 is an example of the “fourth conductive member”.

The sealing resin 7 covers a portion of each of the first lead 1A, the second lead 1B, and the third lead 1C, the semiconductor element 3, and the bonding wires 4. The sealing resin 7 may be a black epoxy resin.

As shown in FIGS. 1, 2 and 4 to 6, the sealing resin 7 has a resin obverse surface 71, a resin reverse surface 72, and resin side surfaces 73 to 76. The resin obverse surface 71 and the resin reverse surface 72 face away from each other in the thickness direction z. The resin obverse surface 71 faces the first side in the thickness direction z, and faces the same side as the element obverse surface 301 and the first surface 111. The resin reverse surface 72 faces the second side in the thickness direction z, and faces the same side as the element reverse surface 302 and the second surface 112.

Each of the resin side surfaces 73 to 76 is connected to the resin obverse surface 71 and the resin reverse surface 72, and is located between the resin obverse surface 71 and the resin reverse surface 72 in the thickness direction z. The resin side surface 73 and the resin side surface 74 face away from each other in the first direction x. The resin side surface 73 faces the first side in the first direction x, and the resin side surface 74 faces the second side in the first direction x. The resin side surface 75 and the resin side surface 76 face away from each other in the second direction y. The resin side surface 75 faces the first side in the second direction y, and the resin side surface 76 faces the second side in the second direction y. As shown in FIG. 1, a portion of each first terminal portion 12 protrudes from the resin side surface 74. A portion of each of the second terminal portions 16 and the third terminal portion 22 protrudes from the resin side surface 73. In the illustrated example, each of the resin side surfaces 73 to 76 is slightly inclined to the thickness direction z. Note that the shape of the sealing resin 7 shown in FIGS. 1, 2 and 4 to 6 is merely an example. The shape of the sealing resin 7 is not limited to the illustrated shape.

The following describes advantages of the present embodiment.

In the semiconductor device A10, the second lead 1B includes the first portion 14 and the second portion 15. As viewed in the thickness direction z, the first portion 14 is located on the first side in the first direction x with respect to the die pad 11 of the first lead 1A. As viewed in the thickness direction z, the second portion 15 is located on the first side (left side in FIG. 3) in the second direction y with respect to the die pad 11. The second portion 15 is connected to the first portion 14, and extends in the first direction x. The second end portions 4b of the first wires 41 are bonded to the second portion 15. As described above, the second portion 15 connected to and extending from the first portion 14 is used as a portion to which the first wires 41 are bonded, which makes it possible to efficiently bond the first wires 41 (bonding wires 4) to the second portion 15. This prevents an increase of the length of each first wire 41, and can suppress a problem such as a wire sweep.

The second end portions 4b of the first wires 41 are bonded to the second portion 15. The first wires 41 are spaced apart from each other in the first direction x. The first portion 14 extends in the second direction y. The second end portions 4b of the second wires 42 are bonded to the first portion 14. The second wires 42 are spaced apart from each other in the second direction y. According to such a configuration, the second portion 15 and the first portion 14 respectively extending in the first direction x and the second direction y that are perpendicular to each other are used as portions to which the first wires 41 and the second wires 42 are bonded. This makes it possible to efficiently bond the first wires 41 and the second wires 42 to the second portion 15 and the first portion 14. This prevents an increase of the length of each of the first wires 41 and the second wires 42, and can suppress a problem such as a wire sweep. According to the configuration where the second wires 42 and the first wires 41 are bonded to the first portion 14 and the second portion 15, the number of second wires 42 and first wires 41 (the bonding wires 4) can be increased to supply a larger current to the semiconductor element 3.

The semiconductor element 3 is a switching element and has the first obverse-surface electrode 31, the second obverse-surface electrode 32, and the reverse-surface electrode 33. The first obverse-surface electrode 31 is a source electrode, and the second obverse-surface electrode 32 is a gate electrode. The first end portion 4a of each of the first wires 41 and the second wires 42 is bonded to the first obverse-surface electrode 31 (source electrode). The semiconductor device A10 further includes the third lead 1C. The third lead 1C is spaced apart from the first lead 1A and the second lead 1B as viewed in the thickness direction z. The fourth wire 44 is bonded to the third lead 1C and the second obverse-surface electrode 32 of the semiconductor element 3. This configuration is suitable for suppressing a sweep of the bonding wires 4 (the first wires 41 and the second wires 42) and supplying a large current in the semiconductor device A10 provided with the semiconductor element 3, which is a switching element.

### First Variation of the First Embodiment

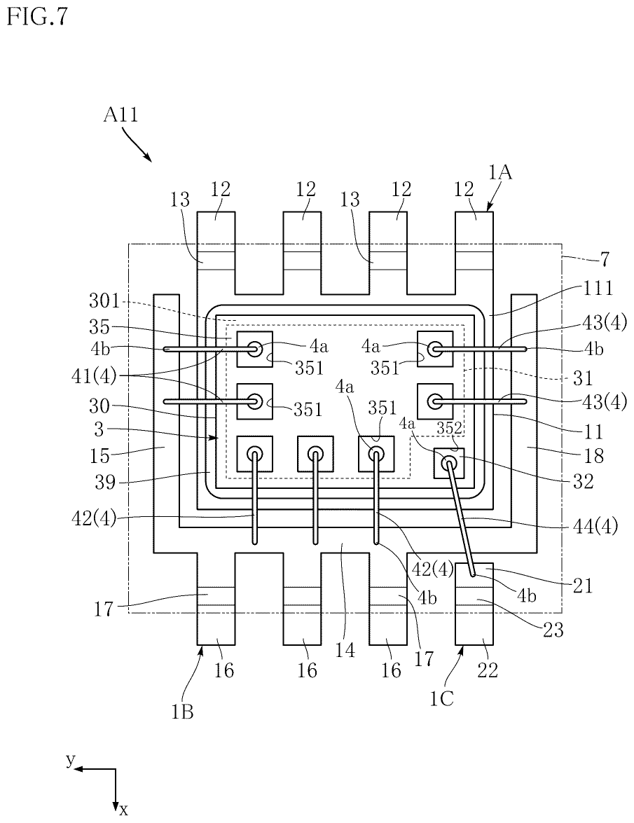

FIG. 7 shows a semiconductor device A11 according to a first variation of the first embodiment. FIG. 7 is a plan view showing the semiconductor device A11. FIG. 7 shows the sealing resin 7 as transparent for convenience of understanding. In FIG. 7 and the subsequent figures, the elements that are identical with or similar to those of the semiconductor device A10 in the above embodiment are designated by the same reference numerals as in the above embodiment, and the descriptions thereof are omitted as appropriate.

The semiconductor device A11 according to the present variation is different from the above embodiment mainly in the configuration of the second lead 1B. In the present variation, the second lead 1B includes a third portion 18. As viewed in the thickness direction z, the third portion 18 is located on the second side (right side in FIG. 7) in the second direction y with respect to the die pad 11. The third portion 18 is connected to the first portion 14, and extends in the first direction x. More specifically, the end of the third portion 18 on the first side (lower side in FIG. 7) in the first direction x is connected to the end of the first portion 14 on the second side (right side in FIG. 7) in the second direction y.

In the present variation, the insulating film 35 arranged on the element obverse surface 301 of the semiconductor element 3 is provided with additional openings 351. The additional openings 351 are arranged along the edge of the first obverse-surface electrode 31 located on the second side in the second direction y.

In the present variation, the bonding wires 4 further include a plurality of third wires 43. Each of the third wires 43 extends in the second direction y as viewed in the thickness direction z. The first end portion 4a of each third wire 43 is bonded to the first obverse-surface electrode 31 exposed from the openings 351. Specifically, the first end portion 4a of each third wire 43 is bonded to a portion of the first obverse-surface electrode 31 exposed from one of the openings 351 arranged on the second side in the second direction y. The second end portion 4b of each third wire 43 is bonded to the third portion 18 of the second lead 1B. The third wires 43 are spaced apart from each other in the first direction x. Each of the third wires 43 is an example of the “third conductive member”.

According to the semiconductor device A11 of the present variation, the second portion 15 connected to and extending from the first portion 14 is used as a portion to which the first wires 41 are bonded, which makes it possible to efficiently bond the first wires 41 (bonding wires 4) to the second portion 15. This prevents an increase of the length of each first wire 41, and can suppress a problem such as a wire sweep.

The second end portions 4b of the first wires 41 are bonded to the second portion 15. The first wires 41 are spaced apart from each other in the first direction x. The first portion 14 extends in the second direction y. The second end portions 4b of the second wires 42 are bonded to the first portion 14. The second wires 42 are spaced apart from each other in the second direction y. According to such a configuration, the second portion 15 and the first portion 14 respectively extending in the first direction x and the second direction y that are perpendicular to each other are used as portions to which the first wires 41 and the second wires 42 are bonded. This makes it possible to efficiently bond the first wires 41 and the second wires 42 to the second portion 15 and the first portion 14. This prevents an increase of the length of each of the first wires 41 and the second wires 42, and can suppress a problem such as a wire sweep. According to the configuration where the second wires 42 and the first wires 41 are bonded to the first portion 14 and the second portion 15, the number of second wires 42 and first wires 41 (bonding wires 4) can be increased to supply a larger current to the semiconductor element 3.

In the semiconductor device A11, the second lead 1B further includes the third portion 18. The third portion 18 extends in the first direction x, and the second end portions 4b of the third wires 43 are bonded to the third portion 18. The third wires 43 are spaced apart from each other in the first direction x. According to such a configuration, the third portion 18 extending in the first direction x is additionally used as a portion to which the third wires 43 are bonded. This makes it possible to efficiently bond the first wires 41, the second wires 42, and the third wires 43 to the second portion 15, the first portion 14, and the third portion 18. This prevents an increase of the length of each of the first wires 41, the second wires 42, and the third wires 43, and can suppress a problem such as a wire sweep. According to the configuration where the second wires 42, the first wires 41, and the third wires 43 are bonded to the first portion 14, the second portion 15, and the third portion 18, the number of second wires 42, first wires 41, and third wires 43 (bonding wires 4) can be increased to supply a larger current to the semiconductor element 3.

Further, the semiconductor device A11 has the same advantages as the semiconductor device A10 in the above embodiment within the range of the same configuration as that of the semiconductor device A10.

### Second Variation of the First Embodiment

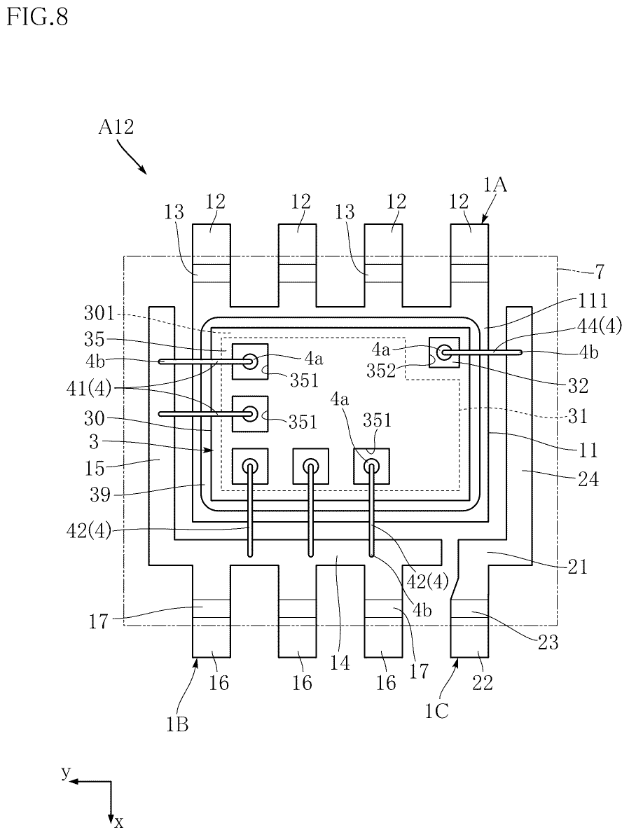

FIG. 8 shows a semiconductor device A12 according to a second variation of the first embodiment. FIG. 8 is a plan view showing the semiconductor device A12. FIG. 8 shows the sealing resin as transparent for convenience of understanding.

The semiconductor device A12 of the present variation is different from the semiconductor device A10 of the above embodiment mainly in the arrangement of the second obverse-surface electrode 32 of the semiconductor element 3 and the configuration of the third lead 1C. In the present variation, the first obverse-surface electrode 31 is arranged over the area of the element obverse surface 301, excluding the periphery and a corner (upper right corner in FIG. 8) of the element obverse surface 301. The second obverse-surface electrode 32 is arranged at a corner (upper right corner in FIG. 8) of the element obverse surface 301.

The third lead 1C further includes a fourth portion 24. As viewed in the thickness direction z, the fourth portion 24 is located on the second side (right side in FIG. 8) in the second direction y with respect to the die pad 11. The fourth portion 24 is connected to the base end portion 21, and extends in the first direction x.

The fourth wire 44 extends in the second direction y as viewed in the thickness direction z. The second end portion 4b of the fourth wire 44 is bonded to the fourth portion 24 of the third lead 1C.

According to the semiconductor device A12 of the present variation, the second portion 15 connected to and extending from the first portion 14 is used as a portion to which the first wires 41 are bonded, which makes it possible to efficiently bond the first wires 41 (bonding wires 4) to the second portion 15. This prevents an increase of the length of each first wire 41, and can suppress a problem such as a wire sweep.

The second end portions 4b of the first wires 41 are bonded to the second portion 15. The first wires 41 are spaced apart from each other in the first direction x. The first portion 14 extends in the second direction y. The second end portions 4b of the second wires 42 are bonded to the first portion 14. The second wires 42 are spaced apart from each other in the second direction y. According to such a configuration, the second portion 15 and the first portion 14 respectively extending in the first direction x and the second direction y that are perpendicular to each other are used as portions to which the first wires 41 and the second wires 42 are bonded. This makes it possible to efficiently bond the first wires 41 and the second wires 42 to the second portion 15 and the first portion 14. This prevents an increase of the length of each of the first wires 41 and the second wires 42, and can suppress a problem such as a wire sweep. According to the configuration where the second wires 42 and the first wires 41 are bonded to the first portion 14 and the second portion 15, the number of second wires 42 and first wires 41 (bonding wires 4) can be increased to supply a larger current to the semiconductor element 3.

In the semiconductor device A12, the third lead 1C includes the fourth portion 24. The fourth portion 24 extends in the first direction x, and the second end portion 4b of the fourth wire 44 is bonded to the fourth portion 24. Such a configuration prevents an increase of the length of the fourth wire 44, and can suppress a problem such as a wire sweep. Further, the semiconductor device A12 has the same advantages as the semiconductor device A10 in the above embodiment within the range of the same configuration as that of the semiconductor device A10.

### Third Variation of the First Embodiment

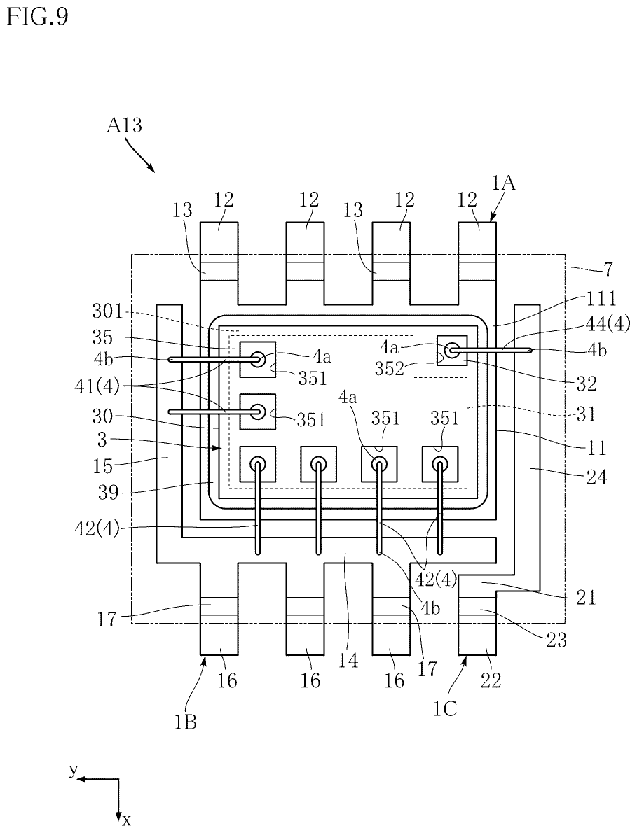

FIG. 9 shows a semiconductor device A13 according to a third variation of the first embodiment. FIG. 9 is a plan view showing the semiconductor device A13. FIG. 9 shows the sealing resin 7 as transparent for convenience of understanding.

The semiconductor device A13 according to the present variation is different from the semiconductor device A12 of the above variation mainly in the configuration of the second lead 1B and the arrangement of the second wires 42. In the present variation, the first portion 14 of the second lead 1B extends further to the second side in the second direction y as compared to that in the semiconductor device A12. The edge of the first portion 14 on the second side in the second direction y is substantially at the same position as the edge of the die pad 11 on the second side in the second direction y. As the first portion 14 is extended, the number of second wires 42 bonded to the first portion 14 is increased by one as compared to that in the semiconductor device A12. In the third lead 1C, the base end portion 21 is connected to the fourth portion 24 while avoiding interference with the first portion 14 of the second lead 1B.

According to the semiconductor device A13 of the present variation, the second portion 15 connected to and extending from the first portion 14 is used as a portion to which the first wires 41 are bonded, which makes it possible to efficiently bond the first wires 41 (bonding wires 4) to the second portion 15. This prevents an increase of the length of each first wire 41, and can suppress a problem such as a wire sweep.

The second end portions 4b of the first wires 41 are bonded to the second portion 15. The first wires 41 are spaced apart from each other in the first direction x. The first portion 14 extends in the second direction y. The second end portions 4b of the second wires 42 are bonded to the first portion 14. The second wires 42 are spaced apart from each other in the second direction y. According to such a configuration, the second portion 15 and the first portion 14 respectively extending in the first direction x and the second direction y that are perpendicular to each other are used as portions to which the first wires 41 and the second wires 42 are bonded. This makes it possible to efficiently bond the first wires 41 and the second wires 42 to the second portion 15 and the first portion 14. This prevents an increase of the length of each of the first wires 41 and the second wires 42, and can suppress a problem such as a wire sweep. According to the configuration where the second wires 42 and the first wires 41 are bonded to the first portion 14 and the second portion 15, the number of second wires 42 and first wires 41 (bonding wires 4) can be increased to supply a larger current to the semiconductor element 3. In the present variation, the first portion 14 extends further in the first direction x, which makes it possible to increase the number of second wires 42 bonded to the first portion 14. This is more preferable for supplying a large current for the semiconductor element 3.

In the semiconductor device A13, the third lead 1C includes the fourth portion 24. The fourth portion 24 extends in the first direction x, and the second end portion 4b of the fourth wire 44 is bonded to the fourth portion 24. Such a configuration prevents an increase of the length of the fourth wire 44, and can suppress a problem such as a wire sweep. Further, the semiconductor device A13 has the same advantages as the semiconductor device A10 in the above embodiment within the range of the same configuration as that of the semiconductor device A10.

### Fourth Variation of the First Embodiment

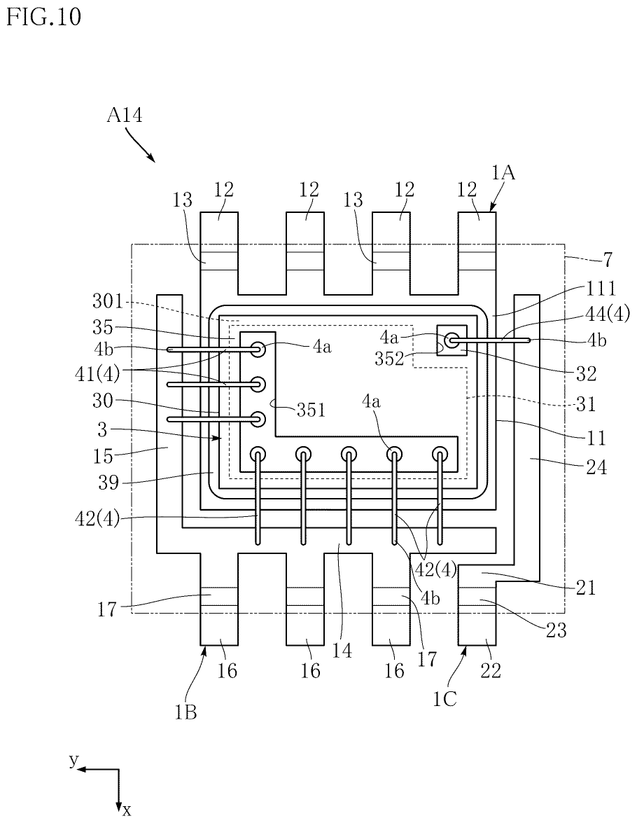

FIG. 10 shows a semiconductor device A14 according to a fourth variation of the first embodiment. FIG. 10 is a plan view showing the semiconductor device A14. FIG. 10 shows the sealing resin 7 as transparent for convenience of understanding.

The semiconductor device A14 of the present variation is different from the semiconductor device A13 of the above variation mainly in the configuration of the insulating film 35 provided on the element obverse surface 301 of the semiconductor element 3 and the arrangement of the first wires 41 and the second wires 42.

In the present variation, the insulating film 35 is formed with an opening 351 having an L-shape extending continuously in the first direction x and the second direction y. Along with the change in the arrangement of the opening 351, the intervals in the first direction x between the first wires 41 bonded to the second portion 15 are smaller than those in the semiconductor device A13. The number of first wires 41 bonded to the second portion 15 is increased by one as compared to that in the semiconductor device A12. The intervals in the second direction y between the second wires 42 bonded to the first portion 14 are smaller than those in the semiconductor device A13. The number of second wires 42 bonded to the first portion 14 is increased by one as compared to that in the semiconductor device A13.

According to the semiconductor device A14 of the present variation, the second portion 15 connected to and extending from the first portion 14 is used as a portion to which the first wires 41 are bonded, which makes it possible to efficiently bond the first wires 41 (bonding wires 4) to the second portion 15. This prevents an increase of the length of each first wire 41, and can suppress a problem such as a wire sweep.

The second end portions 4b of the first wires 41 are bonded to the second portion 15. The first wires 41 are spaced apart from each other in the first direction x. The first portion 14 extends in the second direction y. The second end portions 4b of the second wires 42 are bonded to the first portion 14. The second wires 42 are spaced apart from each other in the second direction y. According to such a configuration, the second portion 15 and the first portion 14 respectively extending in the first direction x and the second direction y that are perpendicular to each other are used as portions to which the first wires 41 and the second wires 42 are bonded. This makes it possible to efficiently bond the first wires 41 and the second wires 42 to the second portion 15 and the first portion 14. This prevents an increase of the length of each of the first wires 41 and the second wires 42, and can suppress a problem such as a wire sweep. According to the configuration where the second wires 42 and the first wires 41 are bonded to the first portion 14 and the second portion 15, the number of second wires 42 and first wires 41 (bonding wires 4) can be increased to supply a larger current to the semiconductor element 3.

Further, in the present variation, the opening 351 of the insulating film 35 is formed to extend continuously, which makes it possible to increase the number of first wires 41 bonded to the second portion 15 and the number of second wires 42 bonded to the first portion 14. This is more preferable for supplying a large current for the semiconductor element 3.

In the semiconductor device A14, the third lead 1C includes the fourth portion 24. The fourth portion 24 extends in the first direction x, and the second end portion 4b of the fourth wire 44 is bonded to the fourth portion 24. Such a configuration prevents an increase of the length of the fourth wire 44, and can suppress a problem such as a wire sweep. Further, the semiconductor device A14 has the same advantages as the semiconductor device A10 in the above embodiment within the range of the same configuration as that of the semiconductor device A10.

### Fifth Variation of the First Embodiment

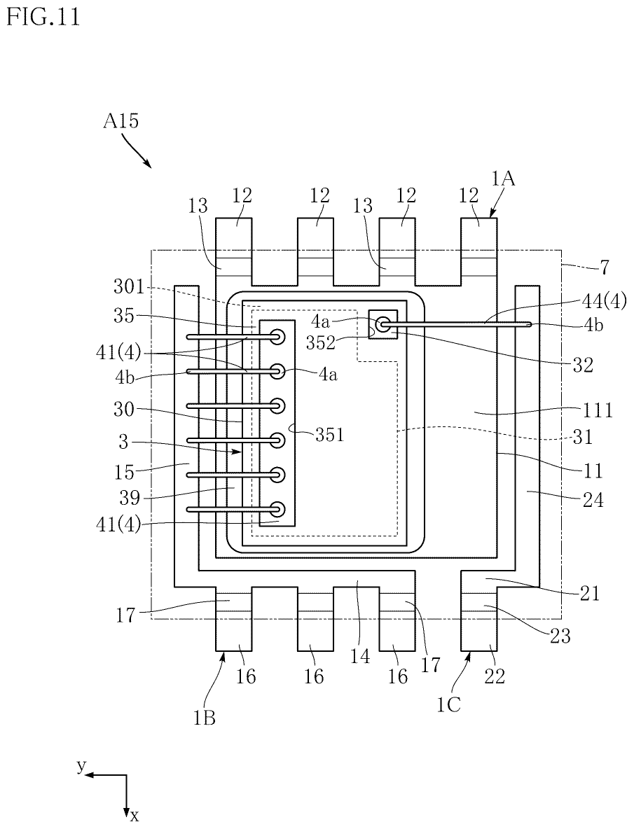

FIG. 11 shows a semiconductor device A15 according to a fifth variation of the first embodiment. FIG. 11 is a plan view showing the semiconductor device A15. FIG. 11 shows the sealing resin 7 as for convenience of transparent understanding.

The semiconductor device A15 of the present variation is different from the above embodiment in the arrangement of the semiconductor element 3, and various changes have been made accordingly. In the present variation, the element body 30 (the semiconductor element 3) has an elongated rectangular shape with a length in the first direction x and a width in the second direction y. The second obverse-surface electrode 32 is arranged at a corner (upper right corner in FIG. 11) of the element obverse surface 301. The insulating film 35 is formed with an opening 351 extending continuously in the first direction x. The opening 351 extends along the edge of the first obverse-surface electrode 31 located on the first side in the second direction y. The intervals in the first direction x between the first wires 41 bonded to the second portion 15 are smaller than those in the semiconductor device A13. The number of first wires 41 bonded to the second portion 15 is increased by c as compared to that in the semiconductor device A10. On the other hand, the semiconductor device A15 does not include the second wires 42.

In the semiconductor device A15, the third lead 1C includes the fourth portion 24. As viewed in the thickness direction z, the fourth portion 24 is located on the second side (right side in FIG. 11) in the second direction y with respect to the die pad 11. The fourth portion 24 is connected to the base end portion 21, and extends in the first direction x. The fourth wire 44 extends in the second direction y as viewed in the thickness direction z. The second end portion 4b of the fourth wire 44 is bonded to the fourth portion 24 of the third lead 1C.

According to the semiconductor device A15 of the present variation, the second portion 15 connected to and extending from the first portion 14 is used as a portion to which the first wires 41 are bonded, which makes it possible to efficiently bond the first wires 41 (bonding wires 4) to the second portion 15. This prevents an increase of the length of each first wire 41, and can suppress a problem such as a wire sweep.

The second end portions 4b of the first wires 41 are bonded to the second portion 15. The first wires 41 are spaced apart from each other in the first direction x. In the present variation, the intervals in the first direction x between the first wires 41 bonded to the second portion 15 are smaller than those in the semiconductor device A13. The element body 30 (the semiconductor element 3) is arranged to have a length in the first direction x, so that more first wires 41 are efficiently arranged. This makes it possible to supply a larger current to the semiconductor element 3. Further, the semiconductor device A15 has the same advantages as the semiconductor device A10 in the above embodiment within the range of the same configuration as that of the semiconductor device A10.

### Sixth Variation of the First Embodiment

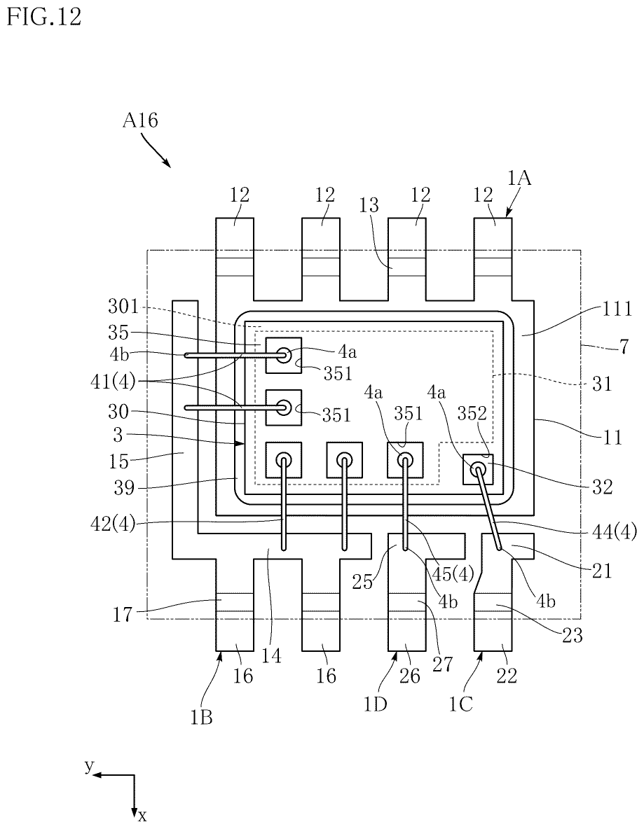

FIG. 12 shows a semiconductor device A16 according to a sixth variation of the first embodiment. FIG. 12 is a plan view showing the semiconductor device A16. FIG. 12 shows the sealing resin 7 as transparent for convenience of understanding.

The semiconductor device A16 of the present variation is different from the semiconductor device A10 of the above embodiment in further including a fourth lead 1D, and various changes have been made accordingly. The fourth lead 1D is arranged between the second lead 1B and the third lead 1C in the second direction y. The fourth lead 1D has a base end portion 25, a fourth terminal portion 26, and a bent portion 27. As viewed in the thickness direction z, the base end portion 25 is located on the first side (lower side in FIG. 12) in the first direction x with respect to the die pad 11. The base end portion 25 is also located on the second side (right side in FIG. 12) in the second direction y with respect to the first portion 14 of the second lead 1B. The base end portion 25 is located on the first side (left side in FIG. 12) in the second direction y with respect to the base end portion 21 of the third lead 1C. The fourth terminal portion 26 is located on the first side (lower side in FIG. 12) in the first direction x with respect to the base end portion 25. The fourth terminal portion 26 extends to the first side in the first direction x. The bent portion 27 connects the base end portion 25 and the fourth terminal portion 26, and is bent as viewed in the second direction y.

In the present variation, the bonding wires 4 further include a fifth wire 45. The fifth wire 45 extends in the first direction x as viewed in the thickness direction z. The first end portion 4a of the fifth wire 45 is bonded to a portion of the first obverse-surface electrode 31 exposed from an opening 351. Specifically, the first end portion 4a of the fifth wire 45 is bonded to a portion of the first obverse-surface electrode 31 (source electrode) exposed from one of the openings 351 arranged on the first side in the first direction x. The second end portion 4b of the fifth wire 45 is bonded to the base end portion 25 of the fourth lead 1D. The fourth terminal portion 26 of the fourth lead 1D functions as a source sense terminal. The source sense terminal is a terminal for detecting the potential of the first obverse-surface electrode 31 (source electrode).

According to the semiconductor device A16 of the present variation, the second portion 15 connected to and extending from the first portion 14 is used as a portion to which the first wires 41 are bonded, which makes it possible to efficiently bond the first wires 41 (bonding wires 4) to the second portion 15. This prevents an increase of the length of each first wire 41, and can suppress a problem such as a wire sweep.

The second end portions 4b of the first wires 41 are bonded to the second portion 15. The first wires 41 are spaced apart from each other in the first direction x. The first portion 14 extends in the second direction y. The second end portions 4b of the second wires 42 are bonded to the first portion 14. The second wires 42 are spaced apart from each other in the second direction y. According to such a configuration, the second portion 15 and the first portion 14 respectively extending in the first direction x and the second direction y that are perpendicular to each other are used as portions to which the first wires 41 and the second wires 42 are bonded. This makes it possible to efficiently bond the first wires 41 and the second wires 42 to the second portion 15 and the first portion 14. This prevents an increase of the length of each of the first wires 41 and the second wires 42, and can suppress a problem such as a wire sweep. According to the configuration where the second wires 42 and the first wires 41 are bonded to the first portion 14 and the second portion 15, the number of second wires 42 and first wires 41 (bonding wires 4) can be increased to supply a larger current to the semiconductor element 3. Further, the semiconductor device A16 has the same advantages as the semiconductor device A10 in the above embodiment within the range of the same configuration as that of the semiconductor device A10.

### Second Embodiment

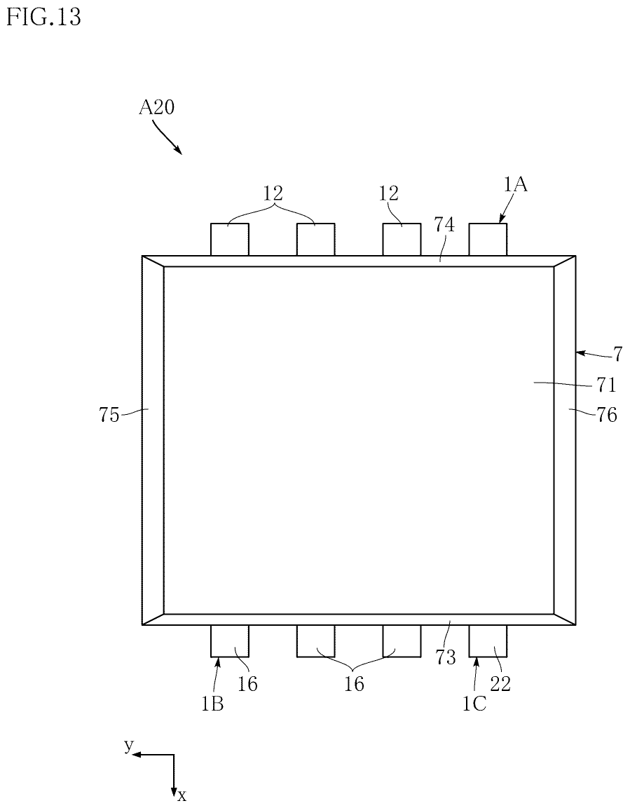

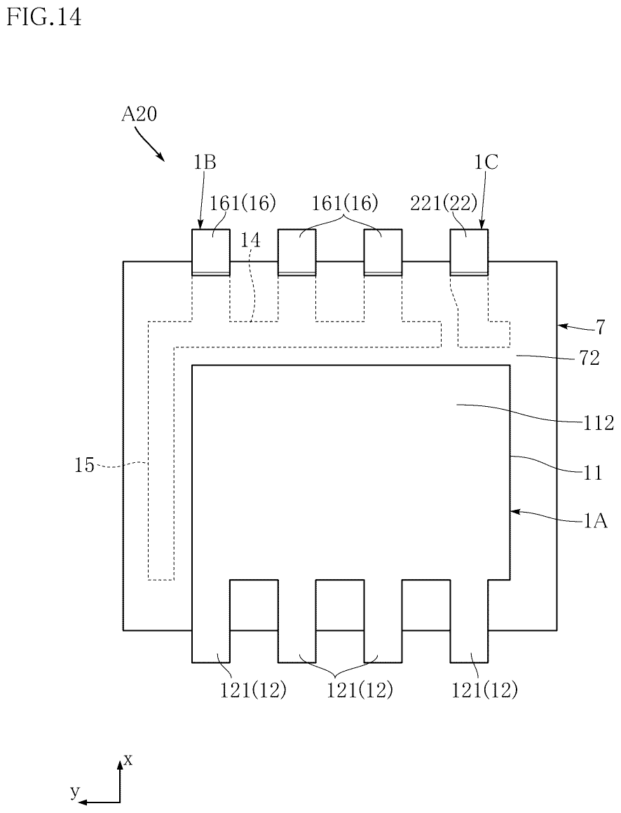

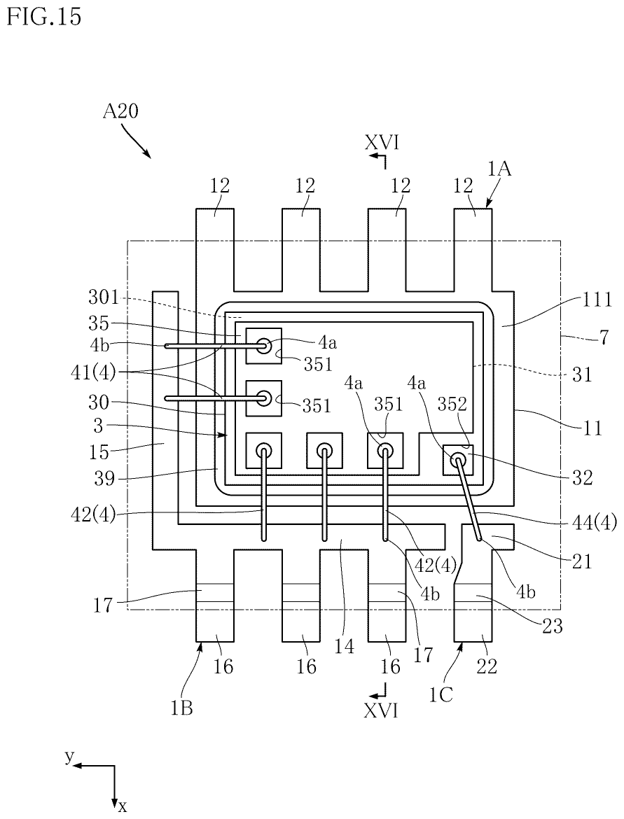

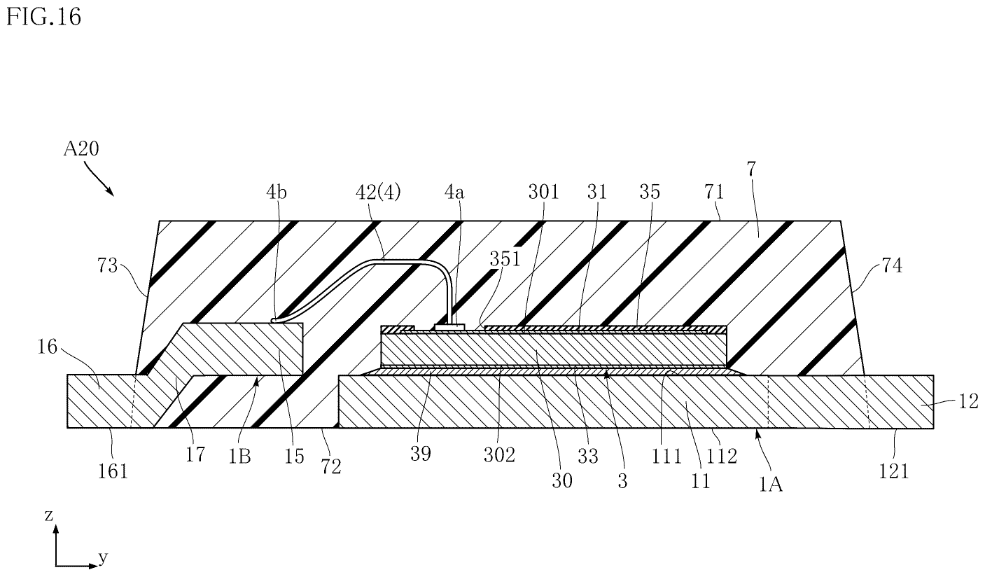

FIGS. 13 to 16 show a semiconductor device A20 according to a second embodiment of the present disclosure. FIG. 13 is a plan view showing the semiconductor device A20. FIG. 14 is a bottom view showing the semiconductor device A20. FIG. 15 is a plan view showing the semiconductor device A20. FIG. 16 is a cross-sectional view along line XVI-XVI in FIG. 16. Note that FIG. 15 shows the sealing resin 7 as transparent for convenience of understanding.

As shown in FIG. 16, the semiconductor device A20 of the present embodiment is different from the above embodiment in the configuration of the first lead 1A. As compared to the above embodiment, the die pad 11 of the present embodiment is located on the second side in the thickness direction z. The second surface 112 of the die pad 11 is exposed from the sealing resin 7. The second surface 112 is bonded with a bonding material such as solder when the semiconductor device A20 is mounted onto a circuit board (not illustrated). The first terminal portions 12 are connected to the end of the die pad 11 on the second side in the first direction x, and extend to the second side in the first direction x. In the present embodiment, the first lead 1A does not have the bent portions 13.

According to the semiconductor device A20 of the present embodiment, the second portion 15 connected to and extending from the first portion 14 is used as a portion to which the first wires 41 are bonded, which makes it possible to efficiently bond the first wires 41 (bonding wires 4) to the second portion 15. This prevents an increase of the length of each first wire 41, and can suppress a problem such as a wire sweep.

The second end portions 4b of the first wires 41 are bonded to the second portion 15. The first wires 41 are spaced apart from each other in the first direction x. The first portion 14 extends in the second direction y. The second end portions 4b of the second wires 42 are bonded to the first portion 14. The second wires 42 are spaced apart from each other in the second direction y. According to such a configuration, the second portion 15 and the first portion 14 respectively extending in the first direction x and the second direction y that are perpendicular to each other are used as portions to which the first wires 41 and the second wires 42 are bonded. This makes it possible to efficiently bond the first wires 41 and the second wires 42 to the second portion 15 and the first portion 14. This prevents an increase of the length of each of the first wires 41 and the second wires 42, and can suppress a problem such as a wire sweep. According to the configuration where the second wires 42 and the first wires 41 are bonded to the first portion 14 and the second portion 15, the number of second wires 42 and first wires 41 (bonding wires 4) can be increased to supply a larger current to the semiconductor element 3. Further, the semiconductor device A20 has the same advantages as the semiconductor device A10 in the above embodiment within the range of the same configuration as that of the semiconductor device A10.

The semiconductor device according to the present disclosure is not limited to those in the above embodiments. Various design changes can be made to the specific configurations of the elements of the semiconductor device according to the present disclosure.

In the above embodiment, a portion of each of the first terminal portions 12, the second terminal portions 16, and the third terminal portion 22 protrudes from either the resin side surface 74 or 73 of the sealing resin 7 in the first direction x. However, the present disclosure is not limited to this configuration. The semiconductor device of the present disclosure may be provided in a package having a configuration where the terminal portions do not protrude from the resin side surfaces of the sealing resin.

The conductive members according to the above embodiment are bonding wires. However, the conductive members are not limited to this configuration, and may be configured as metal plate members instead of the bonding wires.

The present disclosure includes the embodiments described in the following clauses.

### Clause 1

A semiconductor device comprising:
a first lead including a base that includes a first surface facing a first side in a thickness direction;
a second lead spaced apart from the first lead as viewed in the thickness direction;
a semiconductor element mounted on the first surface; and
a plurality of conductive members each including a first end portion and a second end portion,
wherein the semiconductor element includes an element obverse surface facing the first side in the thickness direction, an element reverse surface facing a second side in the thickness direction, and an obverse-surface electrode formed on the element obverse surface,
the first end portion of each of the conductive members is bonded to the obverse-surface electrode,
the second lead includes a first portion and a second portion connected to the first portion,
as viewed in the thickness direction, the first portion is located on a first side in a first direction perpendicular to the thickness direction with respect to the base,
as viewed in the thickness direction, the second portion is located on a first side in a second direction perpendicular to the thickness direction and the first direction with respect to the base, and extends in the first direction, and
the plurality of conductive members include at least one first conductive member whose second end portion is bonded to the second portion.

### Clause 2

The semiconductor device according to clause 1, wherein the plurality of first conductive members are spaced apart from each other in the first direction.

### Clause 3

The semiconductor device according to clause 1 or 2, wherein the plurality of conductive members include at least one second conductive member whose second end portion is bonded to the first portion.

### Clause 4

The semiconductor device according to clause 3, wherein the first portion extends in the second direction, and
the plurality of second conductive members are spaced apart from each other in the second direction.

### Clause 5

The semiconductor device according to clause 4, wherein the second lead includes a third portion connected to the second portion,
as viewed in the thickness direction, the third portion is located on a second side in the second direction with respect to the base, and extends in the first direction, and
the plurality of conductive members include at least one third conductive member whose second end portion is bonded to the third portion.

### Clause 6

The semiconductor device according to any of clauses 1 to 5, further comprising a third lead spaced apart from the first lead and the second lead as viewed in the thickness direction,
wherein the plurality of conductive members include at least one fourth conductive member whose second end portion is bonded to the third lead.

### Clause 7

The semiconductor device according to clause 6, wherein the third lead includes a fourth portion,
as viewed in the thickness direction, the fourth portion is located on the second side in the second direction with respect to the base, and extends in the first direction, and
the second end portion of the at least one fourth conductive member is bonded to the fourth portion.

### Clause 8

The semiconductor device according to clause 1 or 2, wherein the semiconductor element is a switching element,
the obverse-surface electrode includes a first obverse-surface electrode serving as a source electrode, and a second obverse-surface electrode serving as a gate electrode,
the semiconductor device further comprises a third lead spaced apart from the first lead and the second lead as viewed in the thickness direction,
the plurality of conductive members include a fourth conductive member whose second end portion is bonded to the third lead,
the first end portion of the at least one first conductive member is bonded to the first obverse-surface electrode, and
the first end portion of the fourth conductive member is bonded to the second obverse-surface electrode.

### Clause 9

The semiconductor device according to clause 3 or 4, wherein the semiconductor element is a switching element,
the obverse-surface electrode includes a first obverse-surface electrode serving as a source electrode, and a second obverse-surface electrode serving as a gate electrode,
the semiconductor device further comprises a third lead spaced apart from the first lead and the second lead as viewed in the thickness direction,
the plurality of conductive members include a fourth conductive member whose second end portion is bonded to the third lead,
the first end portion of each of the at least one first conductive member and the at least one second conductive member is bonded to the first obverse-surface electrode, and
the first end portion of the fourth conductive member is bonded to the second obverse-surface electrode.

### Clause 10

The semiconductor device according to clause 8 or 9, wherein the third lead includes a fourth portion,
as viewed in the thickness direction, the fourth portion is located on a second side in the second direction with respect to the base, and extends in the first direction, and
the second end portion of the fourth conductive member is bonded to the fourth portion.

### Clause 11

The semiconductor device according to clause 5, wherein the semiconductor element is a switching element,
the obverse-surface electrode includes a first obverse-surface electrode serving as a source electrode, and a second obverse-surface electrode serving as a gate electrode,
the semiconductor device further comprises a third lead spaced apart from the first lead and the second lead as viewed in the thickness direction,
the plurality of conductive members include a fourth conductive member whose second end portion is bonded to the third lead,
the first end portion of each of the at least one first conductive member, the at least one second conductive member, and the at least one third conductive member is bonded to the first obverse-surface electrode, and
the first end portion of the fourth conductive member is bonded to the second obverse-surface electrode.

### Clause 12

The semiconductor device according to any of clauses 1 to 11, further comprising a sealing resin covering the semiconductor element, at least a portion of each of the first lead and the second lead, and the plurality of conductive members,
the first lead includes at least one first terminal portion connected to an end of the base on the second side in the first direction and exposed from the sealing resin, and
the second lead includes at least one second terminal portion connected to an end of the first portion on the first side in the first direction and exposed from the sealing resin.

### Clause 13

The semiconductor device according to clause 12, wherein the at least one first terminal portion extends from the sealing resin to the second side in the first direction, and
the at least one second terminal portion extends from the sealing resin to the first side in the first direction.

### Clause 14

The semiconductor device according to any of clauses 1 to 13, wherein each of the conductive members is a bonding wire.

### REFERENCE NUMERALS

A10, A11, A12, A13, A14, A15, A16, A20: Semiconductor device
1A: First lead 1B: Second lead
1C: Third lead 1D: Fourth lead
11: Die pad (Base) 111: First surface
112: Second surface 12: First terminal portion
121: Reverse-surface mounting portion 13: Bent portion
14: First portion 15: Second portion
16: Second terminal portion
161: Reverse-surface mounting portion
17: Bent portion 18: Third portion
21: Base end portion 22: Third terminal portion
221: Reverse-surface mounting portion 23: Bent portion
24: Fourth portion 25: Base end portion
26: Fourth terminal portion 27: Bent portion
3: Semiconductor element 30: Element body
301: Element obverse surface 302: Element reverse surface
31: First obverse-surface electrode
32: Second obverse-surface electrode
33: Reverse-surface electrode 35: Insulating film
351, 352: Opening 39: Conductive bonding member
4: Bonding wire (Conductive member) 4a: First end portion
4b: Second end portion
41: First wire (First conductive member)
42: Second wire (Second conductive member)
43: Third wire (Third conductive member)
44: Fourth wire (Fourth conductive member)
45: Firth wire 7: Sealing resin
71: Resin obverse surface 72: Resin reverse surface
73, 74, 75, 76: Resin side surface x: First direction
y: Second direction z: Thickness direction

1. A semiconductor device comprising:
a first lead including a base that includes a first surface facing a first side in a thickness direction;
a second lead spaced apart from the first lead as viewed in the thickness direction;
a semiconductor element mounted on the first surface; and
a plurality of conductive members each including a first end portion and a second end portion,
wherein the semiconductor element includes an element obverse surface facing the first side in the thickness direction, an element reverse surface facing a second side in the thickness direction, and an obverse-surface electrode formed on the element obverse surface,
the first end portion of each of the conductive members is bonded to the obverse-surface electrode,
the second lead includes a first portion and a second portion connected to the first portion,
as viewed in the thickness direction, the first portion is located on a first side in a first direction perpendicular to the thickness direction with respect to the base,
as viewed in the thickness direction, the second portion is located on a first side in a second direction perpendicular to the thickness direction and the first direction with respect to the base, and extends in the first direction, and
the plurality of conductive members include at least one first conductive member whose second end portion is bonded to the second portion.

2. The semiconductor device according to claim 1, wherein the plurality of first conductive members are spaced apart from each other in the first direction.

3. The semiconductor device according to claim 1, wherein the plurality of conductive members include at least one second conductive member whose second end portion is bonded to the first portion.

4. The semiconductor device according to claim 3, wherein the first portion extends in the second direction, and
the plurality of second conductive members are spaced apart from each other in the second direction.

5. The semiconductor device according to claim 4, wherein the second lead includes a third portion connected to the second portion,
as viewed in the thickness direction, the third portion is located on a second side in the second direction with respect to the base, and extends in the first direction, and
the plurality of conductive members include at least one third conductive member whose second end portion is bonded to the third portion.

6. The semiconductor device according to claim 1, further comprising a third lead spaced apart from the first lead and the second lead as viewed in the thickness direction,
wherein the plurality of conductive members include at least one fourth conductive member whose second end portion is bonded to the third lead.

7. The semiconductor device according to claim 6, wherein the third lead includes a fourth portion,
as viewed in the thickness direction, the fourth portion is located on the second side in the second direction with respect to the base, and extends in the first direction, and
the second end portion of the at least one fourth conductive member is bonded to the fourth portion.

8. The semiconductor device according to claim 1, wherein the semiconductor element is a switching element,
the obverse-surface electrode includes a first obverse-surface electrode serving as a source electrode, and a second obverse-surface electrode serving as a gate electrode,
the semiconductor device further comprises a third lead spaced apart from the first lead and the second lead as viewed in the thickness direction,
the plurality of conductive members include a fourth conductive member whose second end portion is bonded to the third lead,
the first end portion of the at least one first conductive member is bonded to the first obverse-surface electrode, and
the first end portion of the fourth conductive member is bonded to the second obverse-surface electrode.

9. The semiconductor device according to claim 3, wherein the semiconductor element is a switching element,
the obverse-surface electrode includes a first obverse-surface electrode serving as a source electrode, and a second obverse-surface electrode serving as a gate electrode,
the semiconductor device further comprises a third lead spaced apart from the first lead and the second lead as viewed in the thickness direction,
the plurality of conductive members include a fourth conductive member whose second end portion is bonded to the third lead,
the first end portion of each of the at least one first conductive member and the at least one second conductive member is bonded to the first obverse-surface electrode, and
the first end portion of the fourth conductive member is bonded to the second obverse-surface electrode.

10. The semiconductor device according to claim 8, wherein the third lead includes a fourth portion,
as viewed in the thickness direction, the fourth portion is located on a second side in the second direction with respect to the base, and extends in the first direction, and
the second end portion of the fourth conductive member is bonded to the fourth portion.

11. The semiconductor device according to claim 5, wherein the semiconductor element is a switching element,
the obverse-surface electrode includes a first obverse-surface electrode serving as a source electrode, and a second obverse-surface electrode serving as a gate electrode,
the semiconductor device further comprises a third lead spaced apart from the first lead and the second lead as viewed in the thickness direction,
the plurality of conductive members include a fourth conductive member whose second end portion is bonded to the third lead,
the first end portion of each of the at least one first conductive member, the at least one second conductive member, and the at least one third conductive member is bonded to the first obverse-surface electrode, and
the first end portion of the fourth conductive member is bonded to the second obverse-surface electrode.

12. The semiconductor device according to claim 1, further comprising a sealing resin covering the semiconductor element, at least a portion of each of the first lead and the second lead, and the plurality of conductive members,
the first lead includes at least one first terminal portion connected to an end of the base on the second side in the first direction and exposed from the sealing resin, and
the second lead includes at least one second terminal portion connected to an end of the first portion on the first side in the first direction and exposed from the sealing resin.

13. The semiconductor device according to claim 12, wherein the at least one first terminal portion extends from the sealing resin to the second side in the first direction, and
the at least one second terminal portion extends from the sealing resin to the first side in the first direction.

14. The semiconductor device according to claim 1, wherein each of the conductive members is a bonding wire.
